(19) United States
(12) Patent Application Publication
(10) Pub. No.: US 2024/0032290 A1
(43) Pub. Date: Jan. 25, 2024

(54) SPLIT-GATE NON-VOLATILE MEMORY, FABRICATION AND CONTROL METHODS THEREOF

(71) Applicant: HeFeChip Corporation Limited, Sai Ying Pun (HK)

(72) Inventor: Geeng-Chuan CHERN, Cupertino, CA (US)

(21) Appl. No.: 17/888,430

(22) Filed: Aug. 15, 2022

(30) Foreign Application Priority Data
Jul. 22, 2022 (CN) CN202210869874.5

(51) Int. Cl. H01L 27/11521; H01L 27/11556

(52) U.S. Cl. CPC H01L 27/11521; H01L 27/11556

(57) ABSTRACT

A split-gate non-volatile memory, fabrication and control methods thereof are disclosed by the present application. The split-gate non-volatile memory includes at least one memory cell. Each memory cell includes: a drain region and an N-type doped source region, both formed in the semiconductor substrate; and a stacked gate, first spacers, a select gate and second spacers, all formed between the N-type doped source region and the drain region. The drain region includes an N-type doped region and a heavily P-type doped region formed in the N-type doped region. The memory cell is advantageous in the prevention of erroneous data determination caused by over-erase, a low programming current and a high reading current. Further, the split-gate structure will not lead to a significant increase in the memory cell's area, enhancing overall performance of the split-gate non-volatile memory.

### CROSS-REFERENCE TO RELATED APPLICATION

This application claims the priority of Chinese patent application number 202210869874.5, filed on Jul. 22, 2022, the entire contents of which are incorporated herein by reference.

### TECHNICAL FIELD

The present invention relates to the field of semiconductor technology and, in particular, to a split-gate non-volatile memory and fabrication and control methods thereof.

### BACKGROUND

Non-volatile memory (NVM) has become one of the common memories used in computers, mobile phones, digital cameras and other electronic devices due to its capability of allowing repeated storage, readout and erasing of data and not losing the stored data upon system shutdown or loss of power.

A typical NVM memory cell includes a semiconductor substrate, a floating gate and a control gate. The control gate is disposed above the floating gate. The floating gate is separated from the semiconductor substrate by a tunneling dielectric layer. During an erase operation on such an NVM memory cell, it is difficult to control the number of electrons discharged from the floating gate. If too many electrons are removed, the floating gate may become positively charged. This phenomenon is called over erase, which may lead to early conduction of a channel under the floating gate before a voltage on the control gate reaches an operating voltage. The over erase issue results in an always “on” memory cell which cannot be switched between “on” and “off” states when the voltage on the control gate switches between the operating voltage and a non-operating voltage. This may cause erroneous data determination.

One method for overcoming the over erase issue involves the use of a program verify circuit designed to verify program operations on memory cells. However, such a program verify circuit is typically complicated. Another more commonly used method is to add a select transistor at a drain side of each memory cell and maintain a channel under the select transistor in an off state. In this way, even when the channel under the floating gate is switched on before the voltage on the control gate reaches the operating voltage due to over erase in the memory cell, the cell current path between the drain and source is cut off and there will be no cell current, thus preventing erroneous data determination. However, the addition of the select transistor would lead to a significant area expansion of the memory cell. With the shrinkage of NVM cell size, it is desirable to obtain NVMs with low programming current and high reading current while not suffering from erroneous data determination caused by over erase. It is also desirable not to significantly increase memory cell area. However, existing NVMs cannot satisfy these requirements, and this is one of the current major challenges in the field of NVM.

### SUMMARY OF THE INVENTION

In order to enable the prevention of erroneous data determination caused by over-erase, a low programming current and a reading current in NVM while not causing a significant increase in memory cell area, the present invention provides a fabrication method for a split-gate NVM. Also provided are a split-gate NVM and a control method thereof.

In one aspect, the present invention provides a fabrication method for a split-gate non-volatile memory, comprising:
providing a semiconductor substrate having a plurality of isolation regions formed therein the semiconductor substrate, adjacent isolation regions defining an active area therebetween;
forming a stacked gate on the active area, wherein the stacked gate has a first side and a second side;
forming a drain region on the first side of the stacked gate, wherein the drain region comprises an N-type doped region and a heavily P-type doped region formed in the N-type doped region;
forming first spacers on the first and second sides of the stacked gate respectively;
forming a select gate on the second side of the stacked gate and wherein the select gate is isolated from the stacked gate by the first spacer;
forming second spacers on the first side of the stacked gate and on a side of the select gate opposite to the first spacer, respectively; and
forming an N-type doped source region on the side of the select gate opposite to the first spacer.

In another aspect, the present invention provides a split-gate non-volatile memory. The split-gate non-volatile memory comprises at least one memory cell. Each memory cell comprises:
an N-type doped source region formed in a semiconductor substrate;
a drain region formed in the semiconductor substrate, wherein the drain region comprises an N-type doped region and a heavily P-type doped region formed in the N-type doped region;
a stacked gate formed between the N-type doped source region and the drain region, wherein the N-type doped region in the drain region extends laterally to a position below a portion of the stacked gate;
first spacers formed on opposite sides of the stacked gate respectively;
a select gate formed between the N-type doped source region and the stacked gate wherein a first side of the select gate is adjacent to and in contact with one of the first spacers and is thereby isolated from the stacked gate; and second spacers formed on the other one of the first spacers and on a second side of the select gate respectively.

In yet another aspect, the present invention provides a control method for a split-gate non-volatile memory, comprising a programming operation performed on a pair of memory cell in the split-gate non-volatile memory as defined above. The stacked gate comprises a control gate. The programming operation comprises:
grounding the semiconductor substrate;
for the selected memory cell, grounding or floating the source region, and applying a negative bias voltage to the drain region and a positive bias voltage to the control gate; and for the unselected memory cell, grounding or floating the source and drain region, and applying a negative bias voltage or 0V to the control gate, and grounding the select gate.

In the split-gate non-volatile memory of the present invention, each memory cell includes: a drain region and an N-type doped source region formed in a semiconductor substrate; and a stacked gate, first spacers and a select gate, formed between the N-type doped source region and the drain region. During operation of the memory cell, on the one hand, the select gate keeps a channel of the memory cell non-conductive, preventing erroneous data determination caused by over-erase. On the other hand, since the channel formed between the N-type doped source region and the drain region in the memory cell is an N-type channel, and as the mobility of electrons is higher than that of holes, a relatively high reading current is allowed in a read operation. In addition, the drain region in the memory cell includes an N-type doped region and a heavily P-type doped region formed in the N-type doped region. A P+/N junction is formed between the two. During a program operation, electrons are concentrated in the N-type doped region, lowering a band-to-band tunneling voltage of the P+/N junction and resulting in a higher probability of tunneling. Under the action of an appropriate operating voltage, electrons that have tunneled can be injected into a floating gate in the stacked gate, reducing the need for electrons in the channel and allowing the use of a lower programming current. Therefore, the memory cell is advantageous in the prevention of erroneous data determination caused by over-erase, a low programming current and a high reading current. Further, the split-gate structure will not lead to a significant increase in the memory cell's area, enhancing overall performance of the split-gate non-volatile memory.

The fabrication and control methods of the present invention have the same or similar advantages as the above-described split-gate non-volatile memory.

### BRIEF DESCRIPTION OF THE DRAWINGS

FIG. 1 is a schematic cutaway view of memory cells in a split-gate NVM according to an embodiment of the present invention.

FIG. 2 is a schematic circuit diagram of a memory cell array in a split-gate NVM according to an embodiment of the present invention.

FIG. 3 is a schematic plan view of the memory cell array of FIG. 2.

FIGS. 4a, 4b and 4c are schematic cutaway views along dashed lines A-A′, B-B′ and C-C′ in FIG. 3 of a structure obtained during the fabrication of a split-gate NVM according to an embodiment of the present invention.

FIGS. 5a, 5b and 5c are schematic cutaway views along dashed lines A-A′, B-B′ and C-C′ in FIG. 3 of a structure obtained during the fabrication of a split-gate NVM according to an embodiment of the present invention.

FIGS. 6a, 6b and 6c are schematic cutaway views along dashed lines A-A′, B-B′ and C-C′ in FIG. 3 of a structure obtained during the fabrication of a split-gate NVM according to an embodiment of the present invention.

FIGS. 7a, 7b and 7c are schematic cutaway views along dashed lines A-A′, B-B′ and C-C′ in FIG. 3 of a structure obtained during the fabrication of a split-gate NVM according to an embodiment of the present invention.

FIGS. 8a, 8b and 8c are schematic cutaway views along dashed lines A-A′, B-B′ and C-C′ in FIG. 3 of a structure obtained during the fabrication of a split-gate NVM according to an embodiment of the present invention.

FIGS. 9a, 9b and 9c are schematic cutaway views along dashed lines A-A′, B-B′ and C-C′ in FIG. 3 of a structure obtained during the fabrication of a split-gate NVM according to an embodiment of the present invention.

FIGS. 10a, 10b and 10c are schematic cutaway views along dashed lines A-A′, B-B′ and C-C′ in FIG. 3 of a structure obtained during the fabrication of a split-gate NVM according to an embodiment of the present invention.

FIGS. 11a, 11b and 11c are schematic cutaway views along dashed lines A-A′, B-B′ and C-C′ in FIG. 3 of a structure obtained during the fabrication of a split-gate NVM according to an embodiment of the present invention.

FIGS. 12a, 12b and 12c are schematic cutaway views along dashed lines A-A′, B-B′ and C-C′ in FIG. 3 of a structure obtained during the fabrication of a split-gate NVM according to an embodiment of the present invention.

FIGS. 13a, 13b and 13c are schematic cutaway views along dashed lines A-A′, B-B′ and C-C′ in FIG. 3 of a structure obtained during the fabrication of a split-gate NVM according to an embodiment of the present invention.

FIGS. 14a, 14b and 14c are schematic cutaway views along dashed lines A-A′, B-B′ and C-C′ in FIG. 3 of a structure obtained during the fabrication of a split-gate NVM according to another embodiment of the present invention.

FIGS. 15a, 15b and 15c are schematic cutaway views along dashed lines A-A′, B-B′ and C-C′ in FIG. 3 of a structure obtained during the fabrication of a split-gate NVM according to another embodiment of the present invention.

FIGS. 16a, 16b and 16c are schematic cutaway views along dashed lines A-A′, B-B′ and C-C′ in FIG. 3 of a structure obtained during the fabrication of a split-gate NVM according to another embodiment of the present invention.

### DESCRIPTION OF REFERENCE NUMERALS IN DRAWINGS

100: Semiconductor Substrate; 110: Stacked Gate; 111: Tunneling Dielectric Layer; 112: First Conductive Material Layer; 112a: First Trench; 113: Inter-gate Dielectric Layer; 114: Second Conductive Material Layer; 114a: Second Trench; 115: Hard Mask Layer; 120: Drain Region; 121: N-type Doped Region; 122: Heavily P-type Doped Region; 130: First Spacer; 140: Select Gate; 141: Gate Dielectric Layer; 142: Third Conductive Material Layer; 150: Second Spacer; 160: Source Region; 170: Interlayer Dielectric Layer; 171: Contact Plug;
10, 20, 40, 60: Etching Processes; 30: Ion Implantation Process; 50: Etch-Back Process.

### DETAILED DESCRIPTION

The split-gate NVM and its fabrication and control methods of the present invention will be described in greater detail below with reference to the accompanying drawings and particular embodiments. From the following description, advantages and features of the present invention will become more apparent. It is to be noted that, as used herein, the terms “first”, “second” and the like may be used to distinguish between similar elements without necessarily implying any particular ordinal or chronological sequence. It is to be understood that the terms so used are interchangeable, whenever appropriate. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

It is to be understood that the drawings are all provided in a very simplified form not necessarily drawn to exact scale for the only purpose of helping to explain the disclosed embodiments in a more convenient and clearer way. Additionally, the spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations. Throughout the drawings, if any component is identical to a labeled one, although such components may be easily identifiable in all the figures, in order for a more clear description of labels to be obtained, not all identical components are labeled and described in the following description and accompanying drawings.

Embodiments of the present invention relate to a split-gate NVM including at least one memory cell as described in the following embodiments. Multiple such memory cells can constitute a memory cell array.

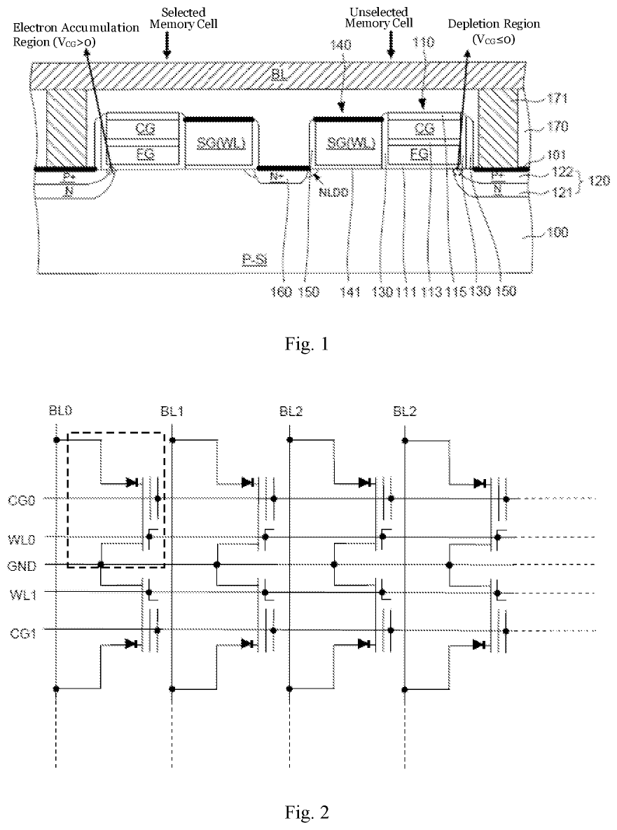

FIG. 1 shows two of the memory cells in the split-gate NVM, which are mirrored to each other and share a common N-type doped source region 160. Referring to FIG. 1, each of the memory cells includes the N-type doped source region 160 and a drain region 120, both formed in the semiconductor substrate 100, as well as a stacked gate 110, first spacers 130 and a select gate 140, all formed on the semiconductor substrate 100 between the N-type doped source region 160 and the drain region 120. Optionally, an N-type lightly doped drain (LDD) (NLDD) region surrounding the N-type doped source region 160 may be formed. The drain region 120 includes an N-type doped region 121 and a heavily P-type doped region 122 formed in the N-type doped region 121. During operation of the memory cell, the heavily P-type doped region 122 is applied with a drain voltage. An N-type dopant ion concentration of the N-type doped region 121 may be lower than or equal to an N-type dopant ion concentration of the N-type doped source region 160.

The stacked gate 110 includes a tunneling dielectric layer 111, a floating gate (FG), an inter-gate dielectric layer 113 and a control gate (CG), which are stacked sequentially one above another, as well as optionally a hard mask layer 115 stacked on the control gate. The N-type doped region 121 in the drain region 120 may extend laterally to a position below a portion of the stacked gate 110 in order to enable, during a program operation with a low operating voltage, easy passage of electrons from the drain region 120 through the tunneling dielectric layer 111 into the floating gate.

A thickness of the tunneling dielectric layer 111 may differ from or be equal to a thickness of the gate dielectric layer 141 located between the select gate 140 and the substrate 100.

The first spacers 130 are formed on opposite sides of the stacked gate 110 respectively. Specifically, one side of the select gate 140 is adjacent to and in contact with the spacer 130 located on one side of the stacked gate 110, and the select gate 140 is thus isolated from the stacked gate 110 by the first spacer 130.

In some embodiments, the memory cell may further include a second spacer 150 formed in adjacent to and in contact with the other first spacer 130 and formed on the other side of the select gate 140. The first spacer 130 and second spacer 150 may include silica, silicon nitride, silicon oxynitride (SiON) or a combination thereof. The memory cell may further include a self-aligned silicide layer 101, or salicide, formed over top surfaces of the select gate, the N-type doped source region 160 and the heavily P-type doped region 122 in the drain region 120.

Further, the semiconductor substrate 100 is, for example, a P-type silicon substrate (P-Si), and the aforementioned N-type doped source region 160 and drain region 120 are directly formed in an upper portion of the P-type silicon substrate. In another embodiment, the semiconductor substrate 100 employs a triple-well structure composed of a P-type silicon substrate, an N-type doped well in the substrate and a P-type doped well located in the N-type doped well and isolated from the substrate. In this case, the aforementioned N-type doped source region 160 and drain region 120 may be formed in an upper portion of the P-type doped well.

According to embodiments of the present invention, the split-gate NVM may include a memory cell array constituted by a plurality of such memory cells. The dashed-line box in FIG. 2 indicates one of the memory cells. The memory cell array may include at least one pair of the memory cells, which are mirrored to each other. The NVM may further include an interlayer dielectric layer 170 covering the memory cells and a plurality of contact plugs 171 each extending through the interlayer dielectric layer 170. The drain regions 120 of a pair of memory cells are connected to a corresponding bit line (BL) through contact plugs 171.

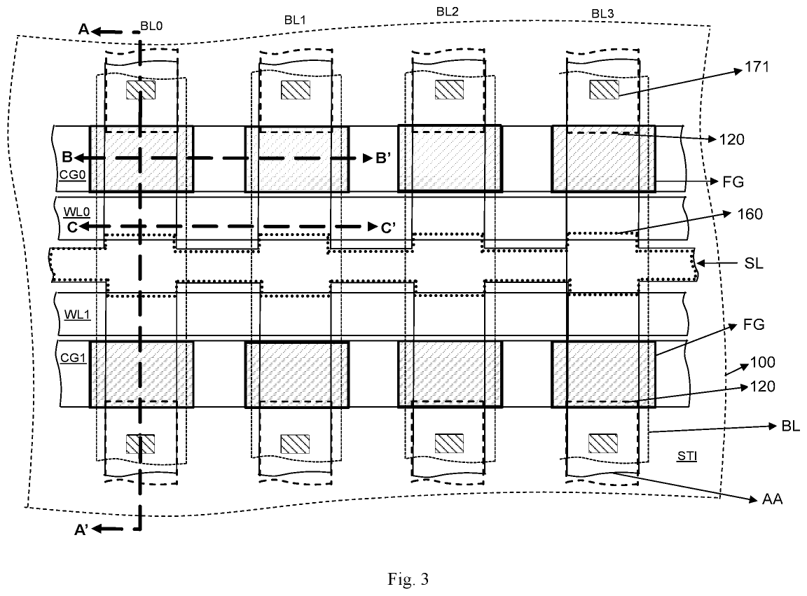

FIG. 3 depicts the locations and ranges of multiple constituent elements in FIG. 2 on the surface of the semiconductor substrate 100. Referring to FIGS. 2 and 3, the memory cell array may include multiple pairs of mirrored memory cells. In the memory cell array, at least two CG lines (e.g., CG0, CG1, . . . in FIGS. 2 and 3) are formed by connecting the control gates which are adjacent and parallel; the N-type doped source regions 160 are connected to form at least one source line (SL, which is grounded (GND) during read operation in this embodiment); and the select gates are connected to form at least one word lines (WLs) (e.g., WL0, WL1, . . . in FIGS. 2 and 3). Referring to FIGS. 1 to 3, the drain regions 120 in the memory cell array are individually connected to at least one BL (e.g., BL0, BL1, BL2, BL3, . . . in FIGS. 2 and 3).

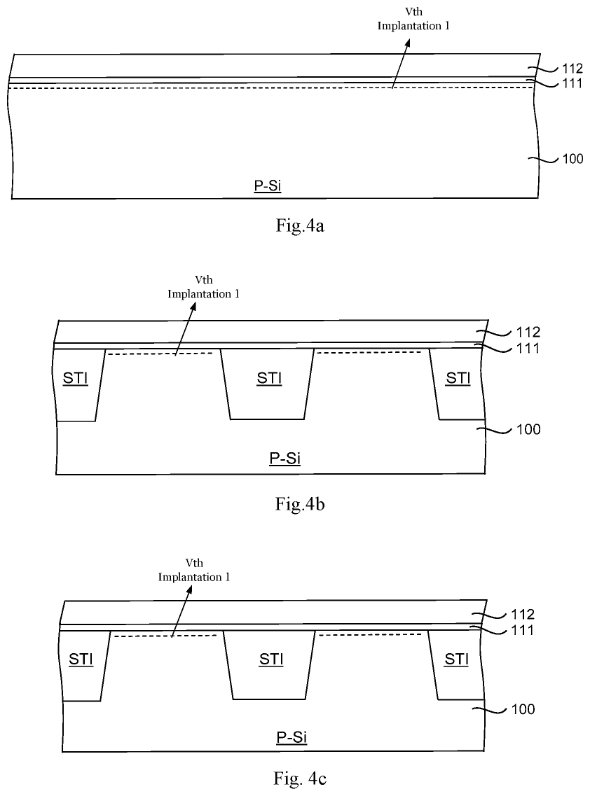

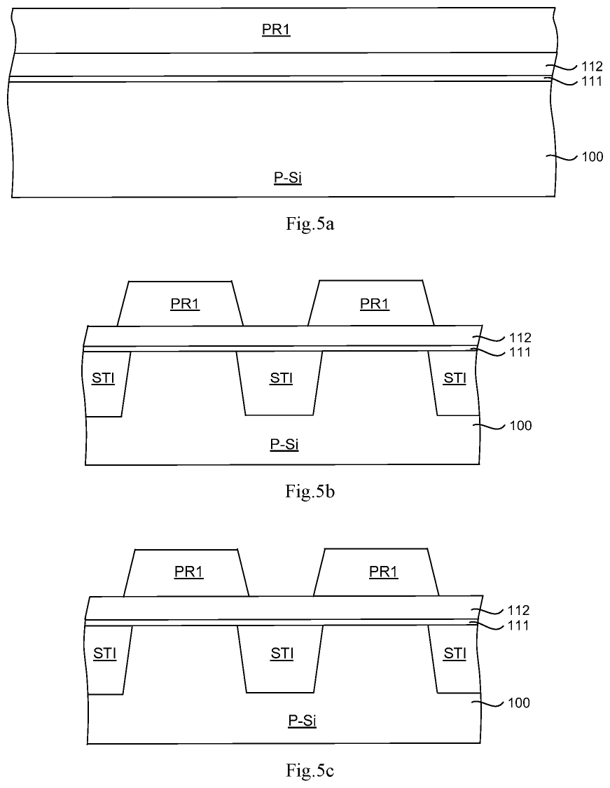

For better illustration of the foregoing embodiments of the present invention, a fabrication method for a split-gate NVM is described below with reference to FIGS. 4a to 16c, in which FIGS. 4a, 4b and 4c are schematic cutaway views of a structure at a single process node along dashed lines A-A′, B-B′ and C-C′ in FIG. 3,; FIGS. 5a, 5b and are schematic cutaway views of a structure at a single process node along dashed lines A-A′, B-B′ and C-C′ in FIG. 3, and so forth. According to one embodiment, the fabrication method includes the processes below.

Referring to FIGS. 4a to 4c, a semiconductor substrate 100 is provided, which is, for example, a P-type silicon substrate (P-Si) or employs the triple-well structure as discussed above. A plurality of isolation (e.g., shallow trench isolation (STI)) regions are formed in the semiconductor substrate 100, and between adjacent STI, an active area (AA) is defined. Subsequently, a tunneling dielectric layer 111 and a first conductive material layer 112 are successively formed. The tunneling dielectric layer 111 may include silica (SiO₂), silicon oxynitride (SiON), hafnium oxide (HfO) or another suitable material and have a thickness of about 6 nm to 12 nm. Optionally, prior to the formation of the first conductive material layer 112, an ion implantation process (e.g., “Vth Implantation 1”, as shown in FIGS. 4a to 4c) may be carried out to adjust a CG threshold voltage (Vth). For example, boron (B) or boron difluoride (BF2) may be implanted at a dose of 1 E12 cm −2 to 1E13 cm⁻² into the semiconductor substrate 100 with energy of 10 KeV to 20 KeV. An annealing process may follow for activating the implanted dopant. The first conductive material layer 112 may include heavily N-type doped polysilicon, silicon-rich SiON or another suitable material.

Referring to FIGS. 5a to 5c, exposure and development processes are then performed to form a patterned photoresist layer PR1 over the first conductive material layer 112. Here, the photoresist layer PR1 is formed to define regions where FGs are to be formed, e.g., along B-B′ (or C-C′) in FIG. 3.

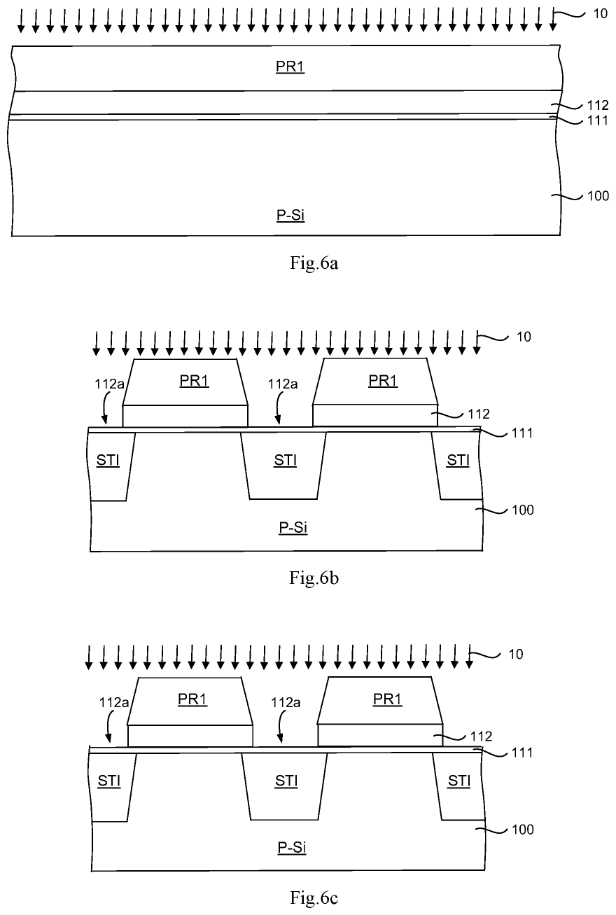

Referring to FIGS. 6a to 6c, afterwards, with the photoresist layer PR1 serving as a mask, an etching process 10 is performed, and a plurality of first trenches 112a along a first direction (e.g., along A-A′ in FIG. 3) in which the tunneling dielectric layer 111 is exposed are formed. The photoresist layer PR1 is removed after the etching process is completed.

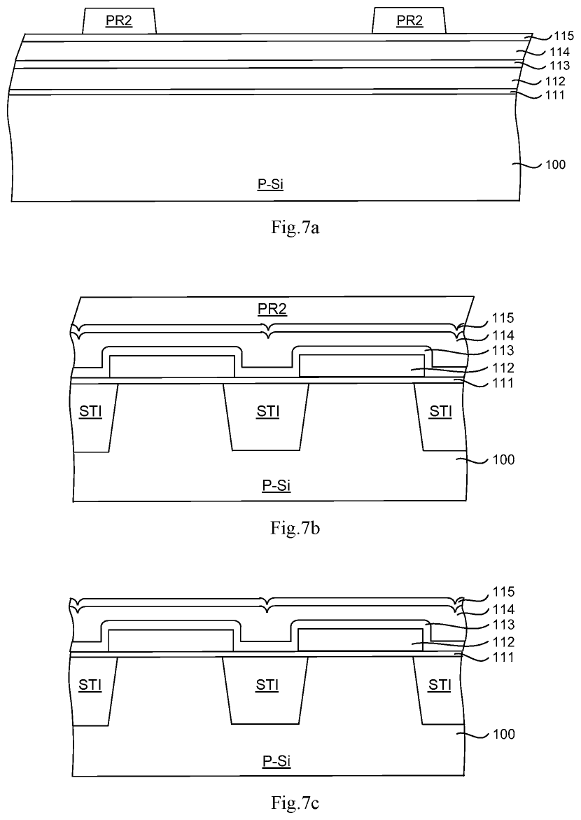

Referring to FIGS. 7a to 7c, after that, an inter-gate dielectric layer 113, a second conductive material layer 114, a hard mask layer 115 and a patterned photoresist layer PR2 are successively formed over the first conductive material layer 112 and the first trenches 112a. The inter-gate dielectric layer 113 may include at least one of an oxide, a nitride and an oxynitride. For example, it may include an ONO stack consisting of a silica layer, a silicon nitride layer and another silica layer. The second conductive material layer 114 may include heavily N-type doped polysilicon, silicon-rich SiON or another suitable material. The hard mask layer 115 may be, for example, silicon nitride. Here, the photoresist layer PR2 is used to define regions where CGs and FGs are to be formed, e.g., along A-A′.

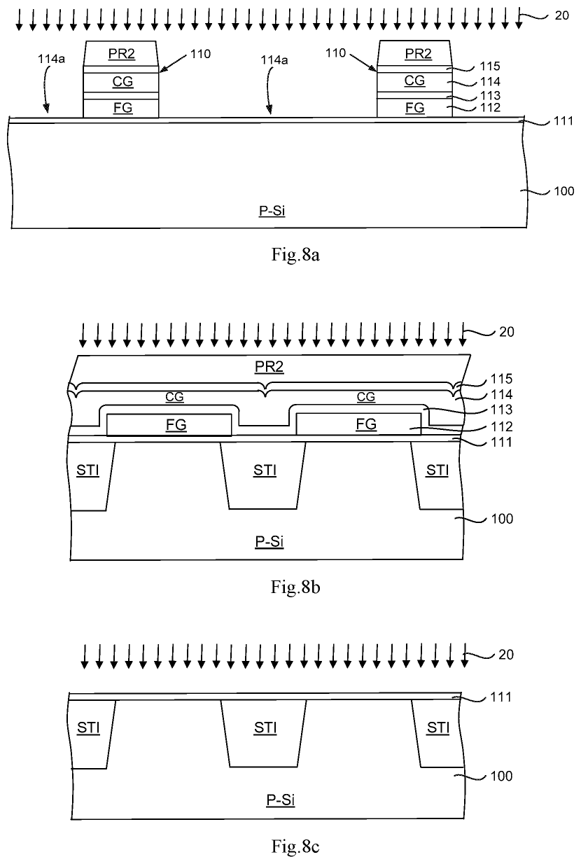

Referring to FIGS. 8a to 8c, subsequently, with the photoresist layer PR2 serving as a mask, an etching process 20 is carried out to etch the hard mask layer 115, the second conductive material layer 114, the inter-gate dielectric layer 113 and the first conductive material layer 112, to form a plurality of second trenches 114a arranged along a second direction (e.g., along B-B′ (or C-C′) in FIG. 3) and stacked gates 110 between adjacent second trenches 114a. The tunneling dielectric layer 111 is exposed in the second trenches 114a. The photoresist layer PR2 is then stripped away. In the stacked gates 110, the first conductive material layer 112 forms floating gates (FGs) and the second conductive material layer 114 forms control gates (CGs). The CGs between adjacent second trenches 114a are connected to form a CG line. Further, referring to FIG. 3, at least two stacked gates 110 are mirrored to each other, with their respective sides away from each other being defined as first sides and their respective sides closer to each other being defined as second sides.

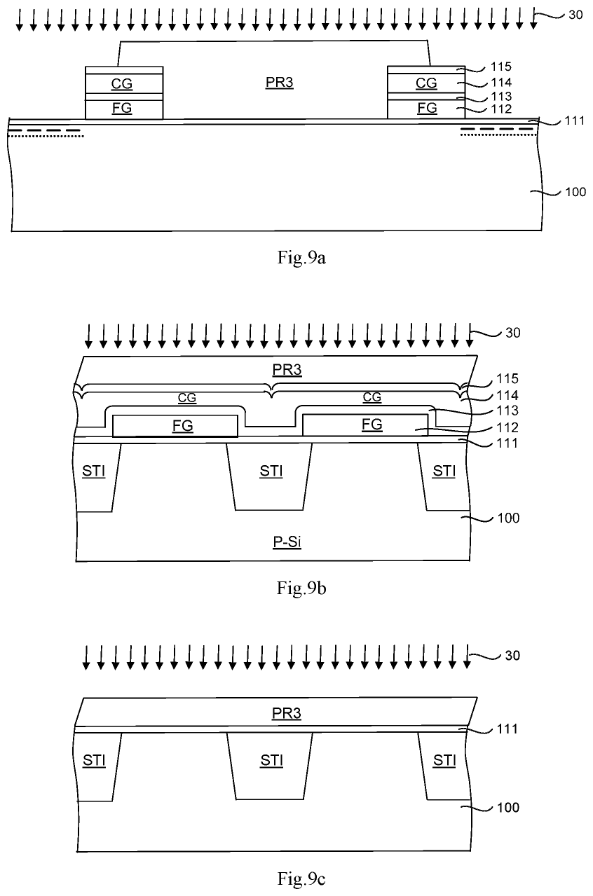

Referring to FIGS. 9a to 9c, a patterned photoresist layer PR3 is then formed to define regions where drain regions are to be formed on the first side of the mirrored stacked gates 110.

Referring to FIG. 9a, with the photoresist layer PR3 serving as a mask that covers the second trenches 114a located between the mirrored stacked gates 110, an ion implantation process 30 is carried out to form the drain regions 120 on the first side of the stacked gates 110. Specifically, N-type ions and P-type ions may be successively implanted. The N-type ions may be implanted by implanting an N-type dopant (e.g., phosphorus or arsenic) into corresponding AA regions at a dose of 8E12 cm′ to 8E14 cm′ with energy of 80 KeV to 150 KeV. The P-type ions may be implanted by implanting a P-type dopant (e.g., boron or boron difluoride) into corresponding AA regions at dose of 1E15 cm′ to 1E16 cm′ with energy of 5 KeV to 25 KeV. The P-type ions may be implanted at a depth (e.g., as indicated by the dashed lines in FIG. 9a) that is shallower than a depth where the N-type ions are implanted (e.g., as indicated by the dotted lines in FIG. 9a). After the ion implantation process for forming the drain regions is completed, the photoresist layer PR3 is removed, and an annealing process is performed to activate the implanted dopants, thus resulting in the formation of the drain regions 120 each including an N-type doped region 121 and a heavily P-type doped region 122. A P+/N junction is formed between the N-type doped region 121 and the heavily P-type doped region 122.

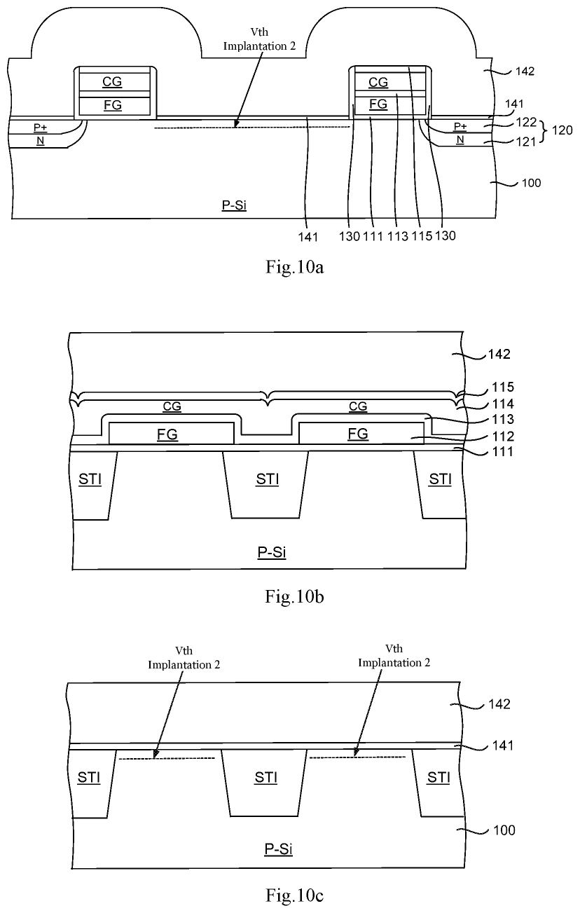

Referring to FIGS. 10a to 10c, following that, first spacers 130 are formed on opposite sides of the stacked gates 110 respectively, and the tunneling dielectric layer 111 in the second trenches 114a are removed by etching. A gate dielectric layer 141 is then formed in the second trenches 114a. The gate dielectric layer 141 may include silica, silicon nitride, SiON, hafnium oxide or another suitable material and have a thickness of about 2 nm to 12 nm. Prior or subsequent to the formation of the gate dielectric layer 141, an implantation process (e.g., “Vth Implantation 2” in FIGS. 10a and 10c) may be carried out to adjust the select gate threshold voltage. For example, boron or boron difluoride may be implanted into the AA between the mirrored stacked gates 110 at a dose of 1E12 cm′ to 1E13 cm⁻² with energy of 10 KeV to 20 KeV. After that, a third conductive material layer 142 is formed, which covers the gate dielectric layer 141 and the stacked gates 110.

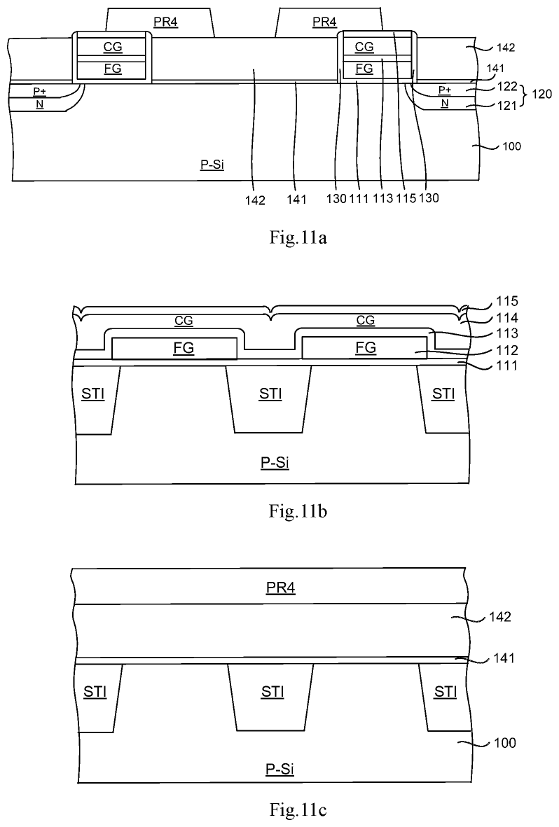

Referring to FIGS. 11a to 11c, subsequently, the third conductive material layer 142 is then planarized (e.g., by chemical mechanical polishing (CMP)), optionally with the hard mask layer 115 on top of the stacked gates 110 serving as a stop layer for the planarizing process. Afterwards, a patterned photoresist layer PR4 is formed over the semiconductor substrate 100, which defines regions where select gates are to be formed along A-A′, as shown in FIG. 3.

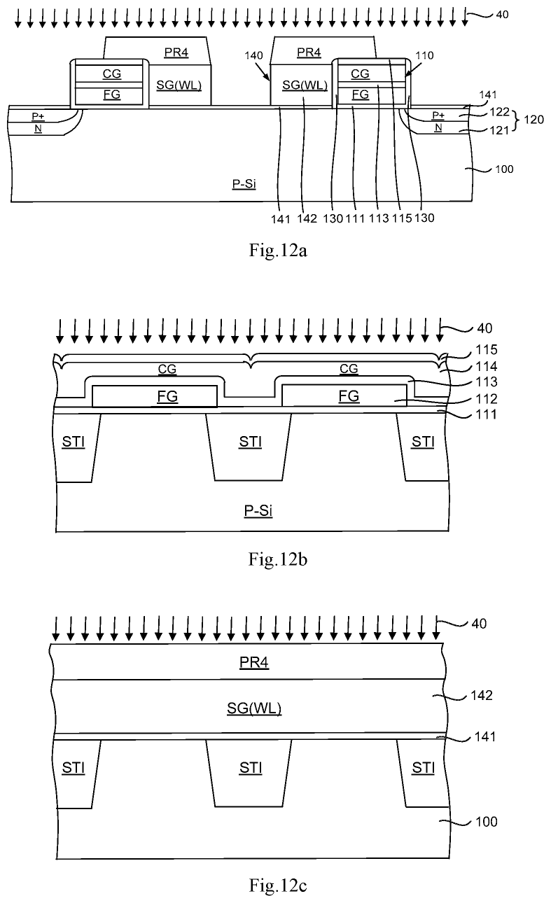

Referring to FIGS. 12a to 12c, with the photoresist layer PR4 serving as a mask, an etching process 40 is performed to etch the third conductive material layer 142. As a result, after the etching process 40 is completed, the third conductive material layer 142 forms mirrored select gates located on the second side of the mirrored stacked gates 110. These multiple pairs of mirrored select gates are connected to form at least two word lines (WLs). The gate dielectric layer 141 not covered by the select gates may be selectively removed during the etching of the third conductive material layer 142.

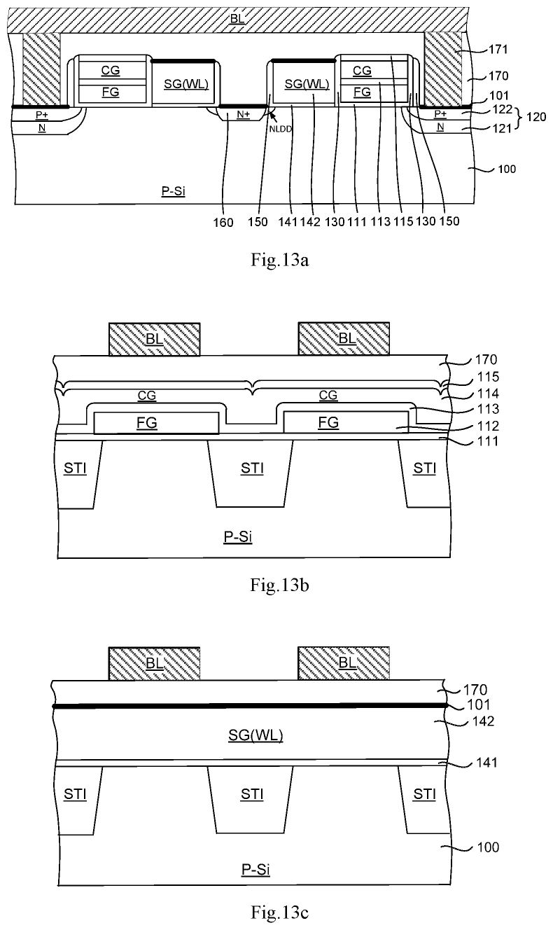

Referring to FIGS. 13a to 13c, afterwards, an N-type LDD implantation process is performed on the side of the select gates 140 opposite to the drain regions 120, and second spacers 150 are formed on the first side of the stacked gates 110 and on the side of the select gates 140 opposite to the first spacers 130. After that, an N-type implantation process is performed on the side of the select gates 140 opposite to the drain regions 120, followed by an annealing process, resulting in the formation of N-type doped source regions 160 and NLDD regions surrounding the respective N-type doped source regions 160.

As a result of the foregoing steps, a memory cell array consisting of a plurality of split-gate memory cells can be obtained. Referring to FIGS. 13a to 13c, a salicide layer 101 may be further formed over tops surfaces of the aforementioned control gates (CGs), select gates (SGs), N-type doped source regions 160 and drain regions 120, and an interlayer dielectric layer 170 may be deposited, followed by forming contact plugs 171 extending through the interlayer dielectric layer 170 and connecting the respective heavily P-type doped regions 121 in the respective drain regions 120. Subsequently, a metal layer on the interlayer dielectric layer 170 and at least one bit line (BL) through which a voltage can be applied to the drain regions 120 are formed. In this embodiment, the mirrored drain regions 120 are connected to the same BL.

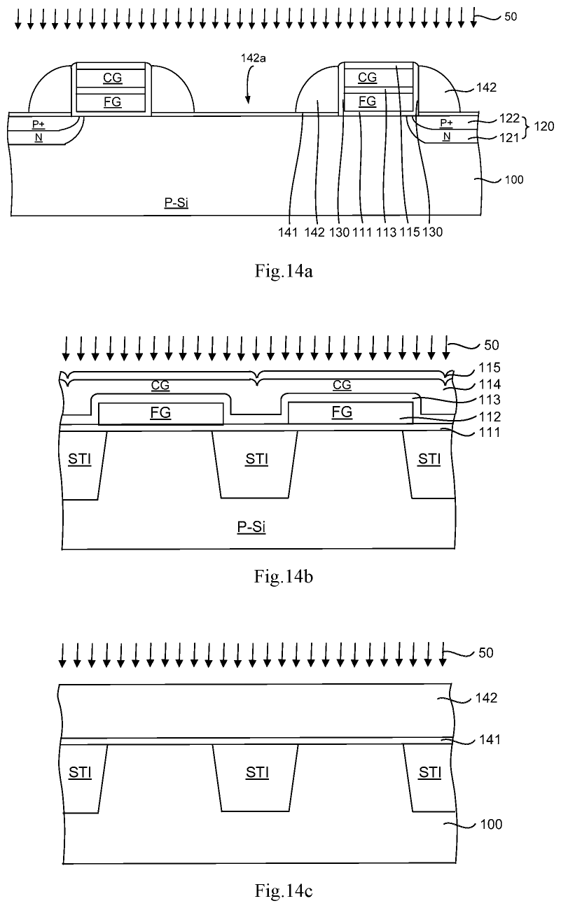

A fabrication method for a split-gate NVM according to another embodiment is described below with reference to FIGS. 14a to 16c. According to this embodiment, the structure shown in FIGS. 10a to 10c can be formed in the same manner as the above-described method, so the fabrication method according to this embodiment will be described on the basis of the structure shown in FIGS. 10a to 10c.

Referring to FIGS. 14a to 14c, in this embodiment, after the third conductive material layer 142 is formed, an anisotropic etch-back process 50 is first performed to partially remove the third conductive material layer 142. As a result, a portion of the third conductive material layer 142 remains only on each side of the stacked gates 110. The remainder of the third conductive material layer 142 covers side faces of the first spacers 130 with a shape of the spacer.

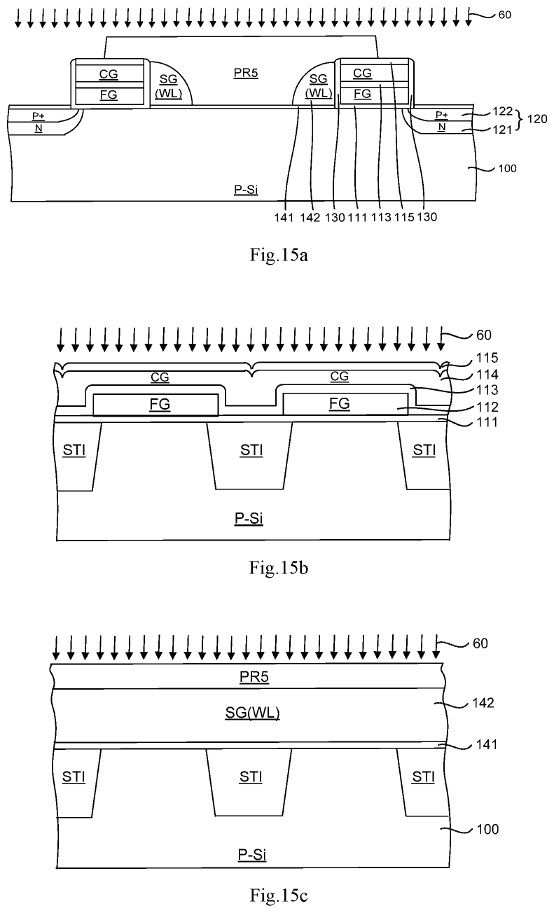

Referring to FIGS. 15a to 15c, a patterned photoresist layer PR5 is then formed, and an etching process 60 is performed with the photoresist layer PR5 serving as a mask. As a result, the third conductive material layer 142 located on the first side of the mirrored stacked gates 110 is removed. After the etching process 60 is completed, the remainder of the third conductive material layer 142 forms select gates (SGs) on the second side of the stacked gates 110. These multiple pairs of mirrored select gates are connected to form at least two word lines (WLs). Following that, the photoresist layer PR5 is stripped away.

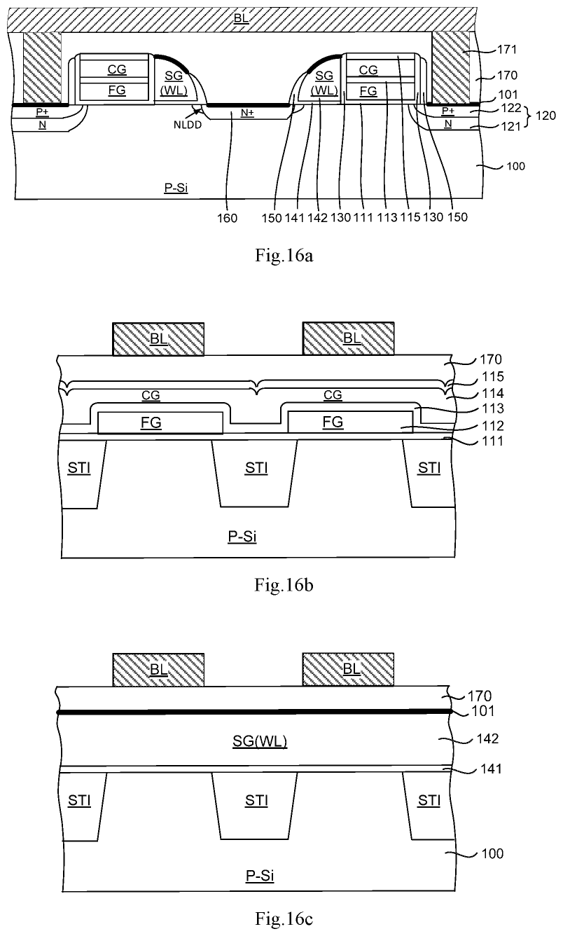

Referring to FIGS. 16a to 16c, afterwards, N-type doped source regions 160 and NLDD regions surrounding them, second spacers 150, a salicide layer 101, an interlayer dielectric layer 170, contact plugs 171 and at least one bit line (BL) are formed in similar manners as the above-described embodiment.

A control method for a split-gate NVM constructed according to any one of the foregoing embodiments will be described. The control method may include a programming, erasing or reading operation performed on a selected memory cell in the split-gate NVM. The control method will be described below with reference to FIGS. 1 and 2 in the exemplary context with the memory cell on the left in FIG. 1 being implemented as the selected memory cell and the memory cell on the right as an unselected memory cell. When describing the operation on the selected memory cell in the memory cell array, for the sake of brevity, a word line (WL) connected to the selected memory cell is referred to as a selected WL, each remaining WL as an unselected WL, a bit line (BL) connected to the selected memory cell as a BL, each remaining BL as an unselected BL, a control gate (CG) line connected to the selected memory cell as a selected CG line and each remaining CG line as an unselected CG lines.

In one embodiment, during a programming operation on the selected memory cell in the memory cell array, the semiconductor substrate 100 is grounded, with the N-type doped source regions 160 in the individual memory cells being grounded or floating. Moreover, a negative bias voltage is applied to the drain region 120 in the selected memory cell, and a positive bias voltage is applied to the CG in the selected memory cell.

Table 1 presents bias voltage conditions for the programming operation performed on the selected memory cell in the memory cell array of FIG. 2 (e.g., the memory cell indicated by the dashed box in FIG. 2) according to an embodiment of the present invention. Referring to Table 1, during the program operation on the selected memory cell, a bias voltage on the selected word line (WL) ranges from 0V to Vdd (power supply voltage) or does not need to be taken care of, and the unselected WL is grounded (0V). Moreover, the bias voltage on the selected CG line ranges from 8V to 14V, and the unselected CG line is applied with a bias voltage ranging from −3V to 0 V. In addition, the bias voltage on the selected bit line (BL) ranges from −12V to −6V, and the unselected bit line (BL) is applied with a bias voltage of 0V or floating. Further, source lines (SLs) are grounded or floating, and the semiconductor substrate 100 is grounded (0V).

TABLE 1
Program Bias Conditions

| Terminal | Bias Voltage |
|---|---|
| Selected WL | 0 V to Vdd or don't care |
| Unselected WL | 0 V |
| Selected CG | 8 V to 14 V |
| Unselected CG | −3 V to 0 V |
| Source lines | 0 V or floating |
| Selected BL | (−12) V to (−6) V |
| Unselected BL | 0 V or floating |
| Semiconductor substrate | 0 V |

During this programming operation, when the bias voltage on the selected CG line reaches a preset positive bias voltage (VCG>0, e.g., from 8V to 14V), in the selected memory cell, electrons will accumulate in the N-type doped region 121 around a lower surface of the tunneling dielectric layer 111 (“Electron Accumulation Region” in FIG. 1), resulting in a lower band-to-band tunneling voltage of the P+/N junction between the heavily P-type doped region 122 and the N-type doped region 121 in the drain region 120 and hence a higher probability of tunneling. When the selected BL applies a preset bias voltage (e.g., from −12V to −6V) to the heavily P-type doped region 122 in the drain region 120 via a corresponding contact plug 171, band-to-band tunneling will readily occur in the P+/N junction. As a result, electrons tunnel from the heavily P-type doped region 122 into the N-type doped region 121. Electrons in the N-type doped region 121 are subject to a vertical electric field between the control gate (CG) and the semiconductor substrate 100 and injected into the floating gate (FG), thus accomplishing the programming operation. The electrons injected into the floating gate (FG) may be those resulting from the band-to-band tunneling. This reduces the need of the programming process for electrons from the channel in the selected memory cell, thereby allowing a relative low programming current.

Additionally, in the above programming process, the CG of the unselected memory cell may be applied with a negative bias voltage or 0V (VCG 0, e.g., from −3V to 0V). As a result, in the unselected memory cell, electrons in the N-type doped region 121 around the lower surface of the tunneling dielectric layer 111 are depleted (“Depletion Region” in FIG. 1), making band-to-band tunneling difficult to occur in the P+/N junction in the drain region 120 of the unselected memory cell and leading to a very low (even zero) probability of tunneling. Therefore, it is unlikely for electrons in the drain region 120 to be injected into the floating gate (FG) and undesirably interfere with the programming process.

In one embodiment, during an erase operation on the selected memory cell in the NVM, the semiconductor substrate 100 is grounded, with the N-type doped source regions 160 and the drain regions 120 in the individual memory cells being grounded or floating. Moreover, a preset negative bias voltage is applied to the control gate (CG) in the selected memory cell, and the CG of the unselected memory cell is grounded.

Table 2 presents bias voltage conditions for the erase operation performed on the selected memory cell in the memory cell array of FIG. 2 according to an embodiment of the present invention. The bias voltage data in Table 2 can be applied to the semiconductor substrate 100 not employing the above-described triple-well structure. Referring to Table 2, during the erase operation on the selected memory cell, all word lines (WLs) are applied with a bias voltage which ranges from 0V to Vdd (power supply voltage) or does not need to be taken care of. The bias voltage on the selected CG line ranges from −16V to −8V, and the unselected CG line is grounded (0V). Additionally, the SLs and BLs are grounded or floating, and the semiconductor substrate 100 is grounded (0V).

TABLE 2
Erase Bias Conditions

| Terminal | Bias Voltage |
|---|---|
| All WL | 0 V to Vdd or don't care |
| Selected CG | (−16) V to (−8) V |
| Unselected CG | 0 V |
| SL | 0 V or floating |
| All BL | 0 V or floating |
| Semiconductor substrate | 0 V |

Table 3 presents bias voltage conditions for the erase operation performed on the selected memory cell in the memory cell array of FIG. 2 according to another embodiment of the present invention, which are applicable to the semiconductor substrate 100 employing the above-described triple-well structure. In this case, the P-type silicon substrate, the N-type doped well and the P-type doped well in the triple-well structure may be separately applied with voltages. Erase conditions for a memory cell based on the triple-well structure may differ from those for a memory cell directly formed on the P-type doped semiconductor substrate 100. For memory cells based on the triple-well structure, the selected memory cell is erased by two voltages, i.e., a negative bias voltage on the selected CG line (e.g., in the range of from −4V to −8V) and a positive bias voltage applied to the P-type doped well (e.g., from 4V to 8V).

Referring to Table 3, during the erase operation performed on the selected memory cell based on the triple-well structure, all the WLs are applied with a bias voltage which ranges from 0V to Vdd (power supply voltage) or does not need to be taken care of. The selected CG line is applied with a bias voltage ranging from −4V to −8V, and the unselected CG line is grounded (0V). The source lines (SLs) are grounded, and all the BLs are grounded or floating. In the triple-well structure, the P-type silicon substrate and the N-type doped well are grounded (0V), and the P-type doped well is applied with a bias voltage of from 4V to 8V.

TABLE 3
Erase Bias Conditions (Triple-Well Structure)

| Terminal | Bias Voltage |
|---|---|
| All WL | 0 V to Vdd or don't care |
| Selected CG | (−8) V to (−4) V |
| Unselected CG | 0 V |
| SL | 0 V |
| All BL | 0 V or floating |
| P-type doped well | 4 V to 8 V |
| N-type doped well | 0 V |
| P-type silicon substrate | 0 V |

This erase operation may be accomplished in a block-wise manner. In this case, a plurality of selected memory cells can be erased at the same time. As each of the CG lines that they are connected to is applied with a negative bias voltage (e.g., −16V to −8V), electrons are expelled from the floating gates (FGs). As a result of the electrons leaving the FGs, a threshold voltage (Vth) of the storage transistors in the involved memory cells will be reduced.

In one embodiment, during a reading operation on the selected memory cell in the NVM, the semiconductor substrate 100 is grounded, and the N-type doped source regions 160 in the individual memory cells are also grounded. A positive bias voltage is applied to the drain region 120 in the selected memory cell. The CG is applied with a preset voltage, and the SG with the power supply voltage (Vdd). Additionally, the drain region 120 of the unselected memory cell is grounded or floating, and the SG thereof is grounded (0V).

Table 4 presents bias voltage conditions for the reading operation performed on the selected memory cell in the memory cell array of FIG. 2 according to an embodiment of the present invention. Referring to Table 4, in order to read a datum stored in the selected memory cell, the power supply voltage (Vdd) is applied as a bias voltage to the selected WL, and all the remaining WLs are grounded (0V). All the CG lines or only the selected CG line are/is applied with a bias voltage ranging from −2V to 2V (e.g., 0V), and the bias voltage on the selected bit line (BL) ranges from 1V to 3V, with each remaining BL being applied with a bias voltage of 0V or floating. The SLs are grounded, and the semiconductor substrate 100 is grounded (0V) too.

TABLE 4
Read Bias Conditions

| Terminal | Bias Voltage |
|---|---|
| Selected WL | Vdd |
| Unselected WL | 0 V |
| Selected CG | (−2) V to (+2) V |
| SL | 0 V |
| Selected BL | 1 V to 3 V |
| Unselected BL | 0 V or floating |
| Semiconductor substrate | 0 V |

During the reading operation, if a threshold voltage (Vth) of the storage transistors in the selected memory cell is relatively low, as a result of which, when a preset voltage is applied to the CG, the storage transistors in the selected memory cell will be turned on, and there will be a cell current flowing from the selected bit line (BL) through a P+/N junction in the drain region 120, a channel under the FG and a channel under the SG to the N-type doped source region 160. Upon detecting this, it can be determined that the selected memory cell is in an ON state. If the floating gate (FG) in the selected memory cell is negative charged, no such cell current will be detected when the preset voltage is applied to the CG, and it can be thus determined that the selected memory cell is in an OFF state. In this embodiment, due to the presence of the SGs in the memory cells, during the reading operation on the selected memory cell, the bias voltage on the unselected WL is 0V. As a result, the channels in the memory cells connected to the unselected WL are turned off. Thus, even when the channel under the FG is turned on due to-over erase, there will be no current path being established, avoiding erroneous data determination.

In the split-gate NVM according to embodiments of the present invention, during an erase operation on a memory cell, even when the channel under the floating gate (FG) is turned on due to over-erase before the CG voltage reaches the operating voltage, the SG can cause the channel of the memory cell to remain OFF, thereby avoid erroneous data determination arising from the over-erase. Moreover, since the channel formed between the N-type doped source region 160 and the drain region 120 in the memory cell is an N-type channel, and as the mobility of electrons is higher than that of holes, a relatively high reading current is allowed in a reading operation. Further, during a programming operation, electrons are accumulated in the N-type doped region 121 in the drain region 120, resulting in a lower band-to-band tunneling voltage of the P+/N junction between the heavily P-type doped region 122 and the N-type doped region 121 in the drain region 120 and a high probability of tunneling. Under the action of an appropriate CG voltage and drain voltage, electrons that have tunneled can be injected into the FG, reducing the need for electrons in the channel and allowing the use of a lower programming current.

The foregoing description is merely that of several preferred embodiments of the present invention and is not intended to limit the scope of the claims of the invention in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of the present invention without departing from the scope of the embodiments are intended to fall within the scope of protection of the invention.

What is claimed is:

1. A fabrication method for a split-gate non-volatile memory, comprising:
providing a semiconductor substrate having a plurality of isolation regions formed therein, adjacent isolation regions defining an active area therebetween;
forming a stacked gate on the active area, wherein the stacked gate has a first side and a second side;
forming a drain region on the first side of the stacked gate, wherein the drain region comprises an N-type doped region and a heavily P-type doped region formed in the N-type doped region;
forming first spacers on the first and second sides of the stacked gate respectively;
forming a select gate on the second side of the stacked gate, wherein the select gate is isolated from the stacked gate by the first spacer;
forming second spacers on the first side of the stacked gate and on a side of the select gate opposite to the first spacer, respectively; and
forming an N-type doped source region on the side of the select gate opposite to the first spacer.

2. The fabrication method of claim 1, wherein the formation of the stacked gate comprises:
successively forming a tunneling dielectric layer and a first conductive material layer;
forming a plurality of first trenches arranged along a first direction by photolithography and etching, wherein the tunneling dielectric layer is exposed in the first trenches;
successively forming an inter-gate dielectric layer, a second conductive material layer and a hard mask layer over the first conductive material layer and the first trenches; and
forming a plurality of second trenches arranged along a second direction and the stacked gate by photolithography and etching.

3. The fabrication method of claim 1, wherein the formation of the drain region comprises:
forming the N-type doped region and the heavily P-type doped region by successively implanting N-type ions and P-type ions into the active area on the first side of the stacked gate, wherein the N-type doped region extends laterally to a position below a portion of the stacked gate.

4. The fabrication method of claim 3, wherein the N-type ions are implanted at a dose of 8E12 cm −2 to 8E14 cm⁻² with an energy of 80 KeV to 150 KeV; and the P-type ions are implanted at a dose of 1E15 cm-2 to 1E16 cm⁻² with an energy of 5 KeV to 25 KeV.

5. The fabrication method of claim 2, wherein the formation of the select gate comprises:
forming a gate dielectric layer in the second trenches;
forming a third conductive material layer covering both the gate dielectric layer and the stacked gate;
removing a portion of the third conductive material layer by planarization; and
forming a select gate on the second side of the stacked gate by performing photolithography and etching processes on the third conductive material layer.

6. The fabrication method of claim 2, wherein the formation of the select gate comprises:
forming a gate dielectric layer in the second trenches;
forming a third conductive material layer covering both the gate dielectric layer and the stacked gate;
partially removing the third conductive material layer by an etch-back process so that a portion of the third conductive material layer remains on each side of the stacked gate; and
forming a select gate on the second side of the stacked gate by performing photolithography and etching processes on the portion of the third conductive material layer on the first side of the stacked gate.

7. The fabrication method of claim 5, wherein the formation of the N-type doped source region comprises:
implanting N-type ions into the active area on the side of the select gate opposite to the drain region, and
wherein the fabrication method further comprises, subsequent to the formation of the select gate and prior to the formation of the second spacer, performing an N-type lightly doped drain (LDD) implantation process to the active area on the side of the select gate opposite to the drain region.

8. The fabrication method of claim 6, wherein the formation of the N-type doped source region comprises:
implanting N-type ions into the active area on the side of the select gate opposite to the drain region, and
wherein the fabrication method further comprises, subsequent to the formation of the select gate and prior to the formation of the second spacer, performing an N-type lightly doped drain (LDD) implantation process to the active area on the side of the select gate opposite to the drain region.

9. A split-gate non-volatile memory, comprising at least one memory cell, wherein each memory cell comprises:
an N-type doped source region formed in a semiconductor substrate;
a drain region formed in the semiconductor substrate, wherein the drain region comprises an N-type doped region and a heavily P-type doped region formed in the N-type doped region;
a stacked gate formed between the N-type doped source region and the drain region, wherein the N-type doped region in the drain region extends laterally to a position below a portion of the stacked gate;
first spacers formed on opposite sides of the stacked gate respectively;
a select gate formed between the N-type doped source region and the stacked gate, wherein a first side of the select gate is adjacent to and in contact with one of the first spacers and is thereby isolated from the stacked gate; and
second spacers formed on the other one of the first spacers and on a second side of the select gate respectively.

10. The split-gate non-volatile memory of claim 9, wherein the stacked gate further comprises a hard mask layer.

11. The split-gate non-volatile memory of claim 9, wherein a plurality of the memory cells forms a memory cell array, wherein the memory cell array comprises at least one pair of the memory cells that are mirrored to each other, and wherein each pair of mirrored memory cells share one N-type doped source region.

12. The split-gate non-volatile memory of claim 11, wherein control gates of each pair of mirrored memory cells are adjacent and parallel to each other.

13. The split-gate non-volatile memory of claim 11, wherein the memory cell array comprises a plurality of pairs of mirrored memory cells, and wherein the memory cell array comprises at least one source line, at least two control gate lines and at least two word lines.

14. The split-gate non-volatile memory of claim 9, further comprising:
an interlayer dielectric layer covering each of the memory cells; and
at least one bit line connected to the respective drain regions in the memory cells through contact plugs extending through the interlayer dielectric layer.

15. The split-gate non-volatile memory of claim 9, wherein the semiconductor substrate is provided with a triple-well structure comprising an N-type doped well in a P-type silicon substrate and a P-type doped well in the N-type doped well, and wherein the N-type doped source region and the drain region of the memory cell are formed in an upper portion of the P-type doped well.

16. A control method for a split-gate non-volatile memory, comprising a programming operation performed on a pair of memory cells in the split-gate non-volatile memory of claim 9, wherein the stacked gate comprises a control gate, and wherein the programming operation comprises:
grounding the semiconductor substrate, and grounding or floating the N-type doped source region;
for the selected memory cell, applying a negative bias voltage to the drain region and a positive bias voltage to the control gate; and
for the unselected memory cell, grounding or floating the drain region, applying a negative bias voltage or 0V to the control gate and grounding the select gate.

17. The control method of claim 16, further comprising an erase operation, wherein the erase operation comprises:
grounding the semiconductor substrate, and grounding or floating the N-type doped source region;
for the selected memory cell, grounding or floating the drain region, and applying a negative bias voltage to the control gate; and
for the unselected memory cell, grounding or floating the drain region, and grounding the control gate.

18. The control method of claim 16, further comprising a reading operation, wherein the reading operation comprises:
grounding the semiconductor substrate and the N-type doped source region;
for the selected memory cell, applying a positive bias voltage to the drain region, a preset voltage to the control gate and a power supply voltage to the select gate; and
for the unselected memory cell, grounding or floating the drain region, and grounding the select gate.
